(19) United States
(12) Patent Application Publication
(10) Pub. No.: US 2017/0242070 A1
(43) Pub. Date: Aug. 24, 2017

(54) AUTOMATIC FAILURE IDENTIFICATION AND FAILURE PATTERN IDENTIFICATION WITHIN AN IC WAFER

(71) Applicant: QUALCOMM Incorporated, San Diego, CA (US)

(72) Inventors: Paul Giotta, Redington Beach, FL (US); Sachin Dasnurkar, San Diego, CA (US)

(21) Appl. No.: 15/051,537

(22) Filed: Feb. 23, 2016

(51) Int. Cl. G01R 31/30; G01R 31/28

(52) U.S. Cl. CPC G01R 31/30; G01R 31/2894

(57) ABSTRACT

Embodiments described herein provide a method for identifying failure patterns in electronic devices. The method begins when a limit is determined for a parameter of interest. A series of the electronic devices is then tested using the limit of the parameter of interest. Failing devices are then identified and x and y coordinate values are plotted. Pattern recognition may be used to determine if the failures shown on the coordinate plot fit a failure pattern. The limit of the parameter of interest is then regressed in steps to the mean value of the failing devices and the electronic devices are retested. The failure pattern of the retested devices is examined to determine if the failure pattern fits a failure pattern. If the failure pattern fits a failure pattern then the parameter of interest may be found to affect the yield rate of production for the electronic devices.

### BACKGROUND

Field

The present disclosure relates generally to testing electronic devices at the wafer level. More specifically the present disclosure related to methods and apparatus for a method and apparatus for automatic failure identification of individual failures and failure patterns within an integrated circuit (IC) wafer.

Background

Wireless communication devices have become smaller and more powerful as well as more capable largely due to the improved IC devices, or chips installed in these devices. Increasingly users rely on wireless communication devices for mobile phone use as well as email and Internet access. This improved functionality requires ICs such as system-on-chip (SoC) devices to incorporate a multitude of functions and memory capabilities, all of which may require thorough testing before being installed in the wireless device. These tests can be carried out at various stages in the fabrication of the IC, including the wafer level. At the wafer level, the ICs have not yet been separated into individual chips. The wafers are tested so that failed devices are identified early in the fabrication process so that they may be repaired or discarded before too much assembly occurs.

IC quality may vary across a wafer and may also vary by die. Potential yield losses must be factored into the manufacturing planning in order to ensure that a predetermined number of passing wafers and/or dies are produced when projecting IC yields. Current methods do not provide sufficient data with regard to yield loss due to process-design interaction. As a result, it may be necessary to produce additional wafers to ensure sufficient dies are produced. In some cases, this may result in more wafers and/or dies produced than are ultimately needed.

Various statistical methods have been used to aid in determining which variables in the IC productions process are the source of wafer and die failures. By controlling for the variables, the yield may be increased. Once such statistical technique is known as regression toward the mean. Using regression toward the mean provides a method for pattern recognition. The patterns evaluated are the failures in the wafers.

There is a need in the art for a method and apparatus for identifying failures and failure patterns within an IC wafer.

### SUMMARY

Embodiments described herein provide a method for identifying failure patterns in electronic devices. The method begins when a limit is determined for a parameter of interest. The parameter of interest may be a particular characteristic of the electronic device to be tested. A series of the electronic devices is then tested using the limit of the parameter of interest. Failing devices are identified after the testing has been completed. The identification includes plotting x and y coordinate values for the failing devices. The coordinate plot of the failing devices is then analyzed to determine if the failures fit a failure pattern. Pattern recognition may be used to determine if the failures fit a failure pattern. The limit of the parameter of interest is then adjusted in interval steps to the mean value of the failing devices and the electronic devices are retested. Upon completion of the retesting the failures are examined to determine a failure pattern. If the failure pattern fits a non-random failure pattern then the parameter of interest may be found to affect the yield rate of production for the electronic devices. The process may be repeated for a second parameter of interest.

An additional embodiment provides an apparatus for identifying failure patterns within an electronic device. The apparatus includes: a processor for determining a parameter of interest and a means value of a set of measured values of the parameter of interest; at least one memory for storing a limit value of a parameter of interest; a comparator for comparing test values with the limit value of the parameter of interest; and a pattern recognition processor for determining failure patterns.

A further embodiment provides an apparatus for identifying failure patterns within an electronic device. The apparatus includes: means for determining a limit for a parameter of interest; means for testing a series of electronic devices using the limit of the parameter of interest; means for identifying failing devices of the series of electronic devices based on the limit of the parameter of interest; means for determining if the failing devices of the series of electronic devices fit a failure pattern; means for adjusting the limit of the parameter of interest to the mean value of the failing devices; means for retesting the failing devices using the mean value as the limit of the parameter of interest; and means for determining if the retested failing devices fit a failure pattern.

A yet further embodiment provides a non-transitory computer-readable medium, which when executed, causes a processor to perform the following steps: determining a limit for a parameter of interest; testing a series of electronic devices using the limit of the parameter of interest; identifying failing devices of the series of electronic devices based on the limit of the parameter of interest; determining if the failing devices of the series of electronic devices fit a failure pattern; adjusting the limit of the parameter of interest to the mean value of the failing devices; retesting the failing devices using the mean value as the limit of the parameter of interest; and determining if the retested failing devices fit a failure pattern.

### BRIEF DESCRIPTION OF THE DRAWINGS

FIG. 1 illustrates a bivariate fit of two variables relating to wafer or device failures, in accordance with embodiments described herein.

FIG. 2 illustrates the effect of using regression towards the means on a bivariate fit of two variables relating to wafer or device failure, in accordance with embodiments described herein.

FIG. 3 is a flowchart of a method to identify failures and failure patterns within an IC device or wafer, in accordance with embodiments described herein.

FIG. 4 is a block diagram of an apparatus for performing an automated method to identify failures and failure patterns, in accordance with embodiments described herein.

### DETAILED DESCRIPTION

Various aspects are now described with reference to the drawings. In the following description, for purposes of explanation, numerous specific details are set forth in order to provide a thorough understanding of one or more aspects. It may be evident, however, that such aspect(s) may be practiced without these specific details.

As used in this application, the terms “component,” “module,” “system” and the like are intended to include a computer-related entity, such as, but not limited to hardware, firmware, a combination of hardware and software, software, or software in execution. For example, a component may be, but is not limited to being, a process running on a processor, a processor, an object, an executable, a thread of execution, a program and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets, such as data from one component interacting with another component in a local system, distributed system, and/or across a network such as the Internet with other systems by way of the signal.

As used herein, the term “determining” encompasses a wide variety of actions and therefore, “determining” can include calculating, computing, processing, deriving, investigating, looking up (e.g., looking up in a table, a database or another data structure), ascertaining and the like. Also, “determining” can include resolving, selecting choosing, establishing, and the like.

The phrase “based on” does not mean “based only on,” unless expressly specified otherwise. In other words, the phrase “based on” describes both “based only on” and “based at least on.”

Moreover, the term “or” is intended to man an inclusive “or” rather than an exclusive “or.” That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

The various illustrative logical blocks, modules, and circuits described in connection with the present disclosure may be implemented or performed with a general purpose processor, a digital signal processor (DSP), an application specific integrated circuit (ASIC), a field programmable gate array (FPGA), or other programmable logic device, discrete gate or transistor logic, discrete hardware components or any combination thereof designed to perform the functions described herein. A general purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core or any other such configuration.

The steps of a method or algorithm described in connection with the present disclosure may be embodied directly in hardware, in a software module executed by a processor or in a combination of the two. A software module may reside in any form of storage medium that is known in the art. Some examples of storage media that may be used include RAM memory, flash memory, ROM memory, EPROM memory, EEPROM memory, registers, a hard disk, a removable disk, a CD-ROM, and so forth. A software module may comprise a single instruction, or many instructions, and may be distributed over several different code segments, among different programs and across multiple storage media. A storage medium may be coupled to a processor such that the processor can read information from, and write information to, the storage medium. In the alternative, the storage medium may be integral to the processor.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in software, the functions may be stored as one or more instructions on a computer-readable medium. A computer-readable medium may be any available medium that can be accessed by a computer. By way of example, and not limitation, a computer-readable medium may comprise RAM, ROM, EEPROM, CD-ROM or other optical disk storage, magnetic disk storage, or other magnetic storage devices, or any other medium that can be used to carry or store desired program code in the form of instructions or data structures and that can be accessed by a computer. Disk and disc, as used herein, includes compact disk (CD), laser disk, optical disc, digital versatile disk (DVD), floppy disk, and Blu-ray® disc where disks usually reproduce data magnetically, while discs reproduce data optically with lasers.

Software or instructions may also be transmitted over a transmission medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of transmission medium.

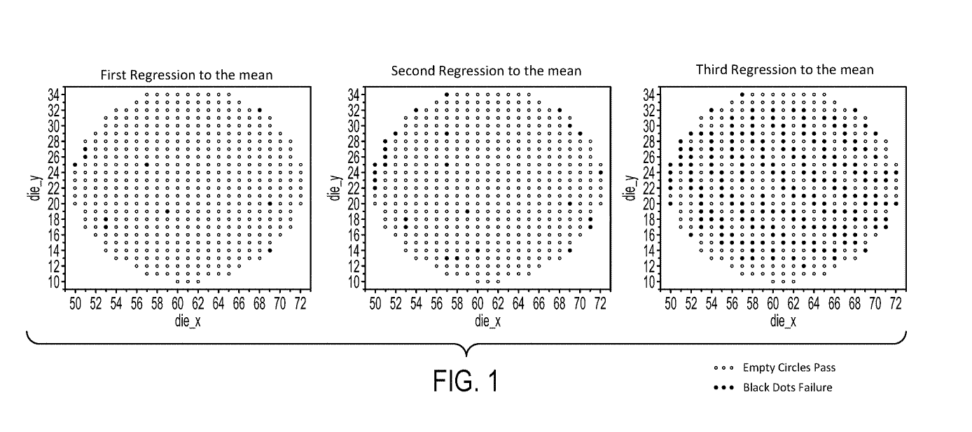

Further, it should be appreciated that modules and/or other appropriate means for performing the methods and techniques described herein, such as those illustrated by FIGS. 1-4, can be downloaded and/or otherwise obtained by a mobile device and/or base station as applicable. For example, such a device can be coupled to a server to facilitate the transfer of means for performing the methods described herein. Alternatively, various methods described herein can be provided via a storage means (e.g., random access memory (RAM), read only memory (ROM), a physical storage medium such as a compact disc (CD) or floppy disk, etc.), such that a mobile device and/or base station can obtain the various methods upon coupling or providing the storage means to the device. Moreover, any other suitable technique for providing the methods and techniques described herein to a device can be utilized.

Embodiments described herein relate to methods for pattern recognition through the use of regression toward the mean. The method begins when a limit is set for the parameter being tested. Failing ICs on the wafer are identified using x and y coordinates. The failures are then examined, and a pattern for the failure is sought. The failure patterns may be examined for specific values that may be of interest, such as power levels recorded during power level testing. The analysis may be extended to the die itself.

Regression toward the mean is a statistical concept that states that if a variable is extreme when it is first measured, then it will tend to be closer to the average value on a second measurement. If the variable is extreme on the second measurement, it will have been closer to the average on the first measurement. The conditions under which regression towards the mean occur depend on the way the term is mathematically defined. Regression toward the mean may be defined for any bivariate distribution with identical marginal distributions.

When regression to the mean is utilized the extreme values measured, whether on a first or second measurement, should be adjusted to bring those values closer to the average value for the variable in question. For an IC, the variable may be location of wafer defects, type of defect, power level test values, or similar values. The values of interest may be determined based on the features and performance specifications of the ICs being tested. The values examined for the regression to the mean analysis may prove to be truly high or low values, whereas other values will merely appear to be so because of some random variation or measurement error. It is these latter type values that tend to move toward the mean value for the variable. This may be alleviated by randomizing and by using control groups of the items being tested. Even if the estimates or variables are unbiased, they may still be subject to random error or noise, and the larger this random error, the larger the regression effect.

FIG. 1 illustrates the plots of two failure variables using a bivariate fit of y by x. The failure variables affect yield loss in IC production and are typically found within an envelope of parameters for a particular IC. The failures occur during both wafer and device production and may occur at various stages in wafer processing. The failures are found within an envelope of parameters for the wafer or IC. A limit is set for each parameter or variable of interest. Failing ICs on the wafer and the die are identified using x and y coordinates. FIG. 1 shows these failures as dots, with each dot having an x and a y coordinate. Once the production run is completed, these failure plots may be examined to determine if there is a pattern to the failures.

A bivariate fit is a form of quantitative statistical analysis. It involves the analysis of two variables, typically designated as x and y, for the purpose of determining the empirical relationship between the. Bivariate analysis may be useful in testing hypotheses of association, however, it cannot and does not determine causality. This type of analysis may help determine and predict a value for one variable if the value of the other variable is known. This type of analysis may be performed with any parametric tests.

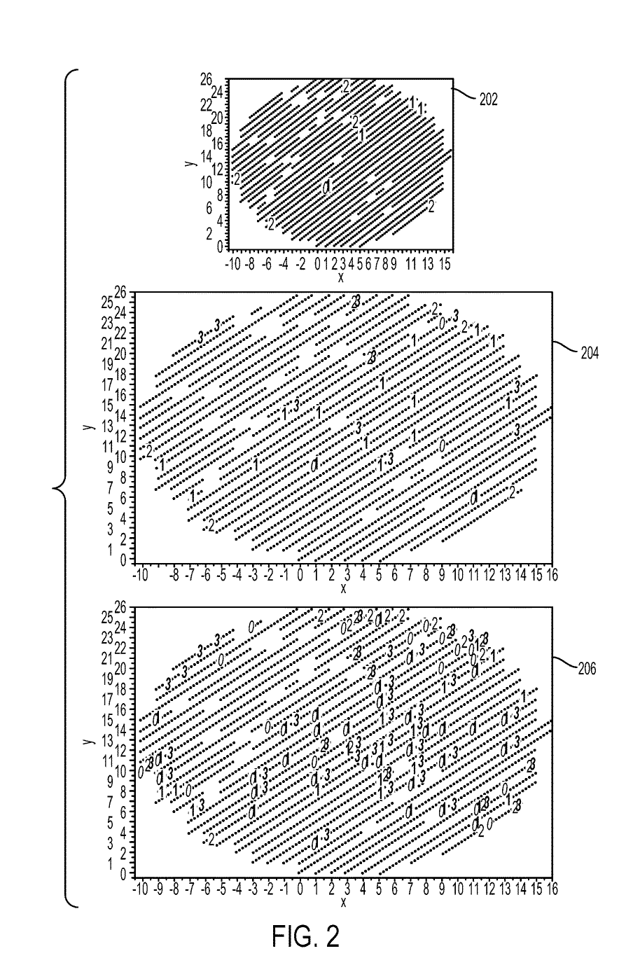

FIG. 2 illustrates the effect of using regression toward the mean on a bivariate analysis of wafer or die failures. In FIG. 2 once again failing wafers or dies are identified using x and y coordinates. Prior to testing a limit is set for the parameter being tested. Once testing has been completed, failing ICs on the die and the wafer are identified and plotted using x and y coordinates. The failures are then examined and a pattern for the failure is sought. Failure patterns may be examined for values of special interest, such as power levels. This analysis may be extended to the die itself.

The first plot 202 in FIG. 2 shows where the limit is set for the value of interest. The dots indicate failures on the wafer, based on the value of interest. The limit is taken and is then adjusted toward the mean of the distribution, or regression toward the mean. As the limit is adjusted toward the mean more failures occur, as seen in the second plot 204 and third plot 206. The third plot illustrates the effect of regression toward the mean with more failures identified, as compared to the second plot. Once the regression toward the mean analysis is complete the plots are analyzed to determine if there is an identifiable pattern or distribution of failures. If the variable being examined has no effect on production output there is no identifiable pattern or distribution of the failure. The pattern identification or distribution may be repeated as the value of interest is moved closer to the mean value. The analysis may be repeated for each value of interest. After examining multiple variables based on the pattern recognition, the variable that influences the process outcome may be determined.

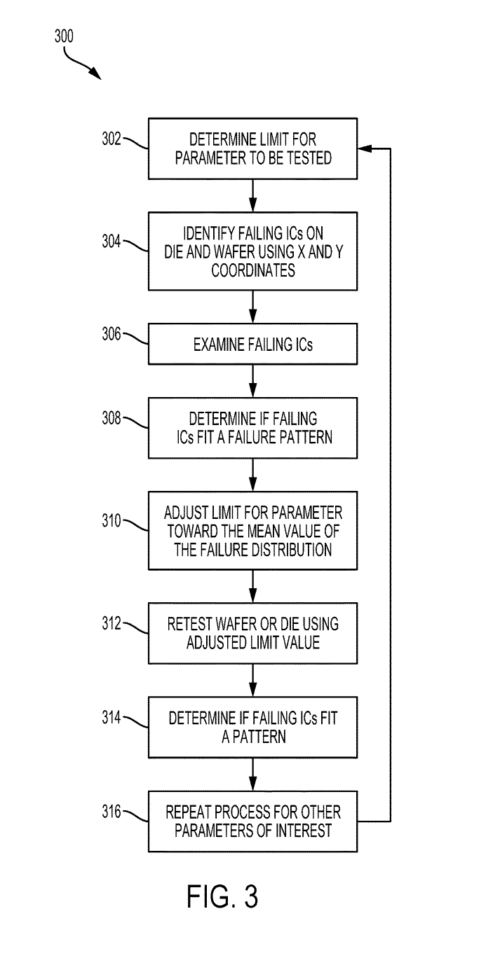

FIG. 3 is a flowchart of a method for identifying failures and failure patterns within an IC device of wafer. The method 300 begins when a parameter to be tested is determined and a limit set for the parameter to be tested in step 302. The test is then conducted for the parameter of interest. After testing, the failing ICs on the die or wafer are identified and located using x and y coordinates in step 304. The failing ICs are examined in step 306. This examination may include the location of the failure and any failure mechanisms that may be present. These failures may have a number of causes, including: bond failure, device failure, over-temperature, among other causes. In step 308 a determination is made to see if the failing ICs fit a failure pattern that is discernible. The determination looks to see if a non-random failure pattern is present. If a pattern for failure is found, then the limit value for the parameter being tested is adjusted toward the mean value of the failure distribution in step 310. This adjustment of the value toward the mean is known as regression toward the mean. The regression toward the mean may be accomplished in interval steps. The wafer or die is then re-tested using the adjusted limit value in step 312. In step 314 the failing ICs are again examined to determine if the failures fit a pattern. If the failures do not fit a pattern, then the parameter or variable has no influence. In step 316 the process is repeated for other parameters of interest, with the process returning to step 302 where a limit is determined for the new parameter of interest.

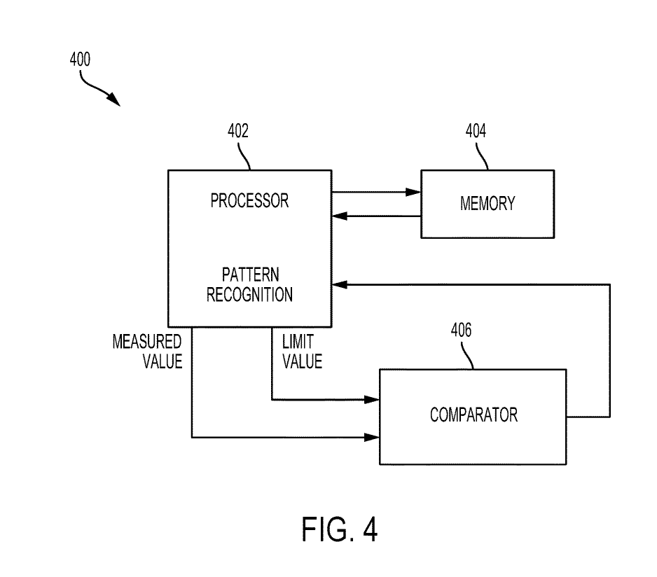

FIG. 4 is a block diagram of an apparatus for performing the method described above. The apparatus executes the automated method of failure identification and failure pattern recognition. The apparatus 400 includes processor 402. Processor 402 performs failure pattern recognition and regression toward the mean as described above. Processor 402 is in communication with memory 404. This communication may be through direct hard-wired connection or may be through a data bus. Memory 404 performs memory address functions and may store additional values needed as part of the specific parameter being tested. For example, in voltage testing the target voltage values may be stored in the memory, as well as an over-voltage limit. Similar values may be stored depending on the parameters being tested. Processor 402 is also in communication with comparator 406. Comparator 406 receives the measured value for the specific parameter being tested and also receives the limit value for the specific parameter. The limit value may be passed to the processor 402 from memory 404. The comparator 406 compares the measured value with the limit value and provides results to the processor 402. Processor 402 may use the results of the comparison to perform pattern recognition on the data received from the comparator 406. Processor 402 may receive similar input for each die or wafer being tested and may perform failure pattern recognition when a threshold number of data points indicating failing devices has been received. Once the pattern recognition operation is complete a determination of the effect of the specific parameter may be assessed. If a failure pattern cannot be discerned from the failure data, then the specific parameter may not be affecting device or wafer yields.

It is understood that the specific order or hierarchy of steps in the processes disclosed is an illustration of exemplary approaches. Based upon design preferences, it is understood that the specific order or hierarchy of steps in the processes may be rearranged. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

It is to be understood that the claims are not limited to the precise configuration and components illustrated above. Various modifications, changes and variations may be made in the arrangement, operation and details of the systems, methods, and apparatus described herein without departing from the scope of the claims.

What is claimed is:

1. A method for identifying failure patterns in electronic devices, comprising:
determining a limit for a parameter of interest;
testing a series of electronic devices using the limit of the parameter of interest;
identifying failing devices of the series of electronic devices based on the limit of the parameter of interest;
determining if the failing devices of the series of electronic devices fit a failure pattern;
adjusting the limit of the parameter of interest to a mean value of the failing devices;
retesting the failing devices using the mean value as the limit of the parameter of interest; and
determining if the retested failing devices fit the failure pattern.

2. The method of claim 1, further comprising:
determining a limit for a second parameter of interest;
testing the series of electronic devices using the limit of the second parameter of interest;
identifying failing devices of the series of electronic devices based on the limit of the second parameter of interest;
determining if the failing devices of the series of electronic devices fit a failure pattern for the second parameter of interest;
adjusting the limit of the second parameter of interest to the mean value of the second parameter of interest for the failing devices;
retesting the failing devices using the mean value of the second parameter of interest for the failing devices as the limit of the second parameter of interest; and
determining if the retested failing devices fit the failure pattern of the second parameter of interest.

3. The method of claim 1, wherein the series of electronic devices comprises a die.

4. The method of claim 1, wherein the series of electronic devices comprises a wafer with multiple integrated circuits.

5. The method of claim 1, wherein the series of electronic devices comprises a production lot of wafers with multiple integrated circuits.

6. The method of claim 2, further comprising determining an influencing parameter of interest based on the failure patterns for the parameter of interest and the second parameter of interest.

7. An apparatus for identifying failure patterns within an electronic device, comprising:
a processor for determining a parameter of interest and a mean value of a set of measured values of the parameter of interest;
at least one memory for storing a limit value of a parameter of interest;
a comparator for comparing test values with the limit value of the parameter of interest; and
a pattern recognition processor for determining failure patterns.

8. An apparatus for identifying failure patterns in electronic devices, comprising:
means for determining a limit for a parameter of interest;
means for testing a series of electronic devices using the limit of the parameter of interest;
means for identifying failing devices of the series of electronic devices based on the limit of the parameter of interest;
means for determining if the failing devices of the series of electronic devices fit a failure pattern;
means for adjusting the limit of the parameter of interest to a mean value of the failing devices;
means for retesting the failing devices using the mean value as the limit of the parameter of interest; and
means for determining if the retested failing devices fit the failure pattern.

9. The apparatus of claim 8, further comprising:
means for determining a limit for a second parameter of interest;
means for testing the series of electronic devices using the limit of the second parameter of interest;
means for identifying failing devices of the series of electronic devices based on the limit of the second parameter of interest;
means for determining if the failing devices of the series of electronic devices fit a failure pattern for the second parameter of interest;
means for adjusting the limit of the second parameter of interest to the mean value of the second parameter of interest for the failing devices;
means for retesting the failing devices using the mean value of the second parameter of interest for the failing devices as the limit of the second parameter of interest; and
means for determining if the retested failing devices fit the failure pattern of the second parameter of interest.

10. The apparatus of claim 8, wherein the means for testing the series of electronic devices tests electronic devices on a die.

11. The apparatus of claim 8, wherein the means for testing the series of electronic devices tests electronic devices on a wafer.

12. The apparatus of claim 8, wherein means for testing the series of electronic devices tests electronic devices in a production lot of wafers with multiple integrated circuits.

13. The apparatus of claim 9, further comprising means for determining an influencing parameter of interest based on the failure patterns for the parameter of interest and the second parameter of interest.

14. A non-transitory computer-readable medium containing instructions, which when executed cause a processor to perform the following steps:
determining a limit for a parameter of interest;
testing a series of electronic devices using the limit of the parameter of interest;
identifying failing devices of the series of electronic devices based on the limit of the parameter of interest;
determining if the failing devices of the series of electronic devices fit a failure pattern;
adjusting the limit of the parameter of interest to the mean value of the failing devices;
retesting the failing devices using the mean value as the limit of the parameter of interest; and
determining if the retested failing devices fit the failure pattern.

15. The non-transitory computer-readable medium of claim 14, further comprising instructions, which when executed cause a processor to perform the following steps:
determining a limit for a second parameter of interest;
testing the series of electronic devices using the limit of the second parameter of interest;
identifying failing devices of the series of electronic devices based on the limit of the second parameter of interest;
determining if the failing devices of the series of electronic devices fit a failure pattern for the second parameter of interest;
adjusting the limit of the second parameter of interest to the mean value of the second parameter of interest for the failing devices;
retesting the failing devices using the mean value of the second parameter of interest for the failing devices as the limit of the second parameter of interest; and
determining if the retested failing devices fit the failure pattern of the second parameter of interest.

16. The non-transitory computer-readable medium of claim 14, wherein the series of electronic devices comprises a die.

17. The non-transitory computer-readable medium of claim 14, wherein the series of electronic devices comprises a wafer with multiple integrated circuits.

18. The non-transitory computer-readable medium of claim 15, further comprising instructions for determining an influencing parameter of interest based on the failure patterns for the parameter of interest and the second parameter of interest.
